(19) United States
(12) Patent Application Publication
(10) Pub. No.: US 2012/0139002 A1
(43) Pub. Date: Jun. 7, 2012

(54) LED PACKAGE STRUCTURE AND METHOD FOR MANUFACTURING THE SAME

(75) Inventor: YAU-TZU JANG, Hsinchu (TW)

(73) Assignee: ADVANCED OPTOELECTRONIC TECHNOLOGY, INC., Hsinchu Hsien (TW)

(21) Appl. No.: 13/267,898

(22) Filed: Oct. 7, 2011

(30) Foreign Application Priority Data
Dec. 6, 2010 (CN) 201010574615.7

(51) Int. Cl. H01L 33/62; H01L 33/48

(52) U.S. Cl. 257/99; 438/27; 257/E33.059; 257/E33.062

(57) ABSTRACT

An LED package structure comprises a substrate, two electrodes arranged on the substrate, an LED chip arranged on the substrate and electrically connected to the electrodes, an encapsulation covering the LED chip, and a shell surrounding the substrate and the encapsulation. The shell includes walls, of a height which exceeds the thickness of the substrate and so functions as a reflector. A circuit structure connected to the electrodes is arranged on the bottom of the walls.

### BACKGROUND

1. Technical Field

The disclosure relates to light emitting diodes, and particularly to an LED package structure and a method for manufacturing the LED package structure.

2. Description of the Related Art

The many advantages of light emitting diodes' (LEDs), such as high luminosity, low operational voltage, low power consumption, compatibility with integrated circuits, ease of driving, long term reliability, and environmental friendliness, have promoted their wide use as a light source. Now, light emitting diodes are commonly applied in environmental lighting.

In order to enhance the luminous efficiency of LEDs, a reflector is usually formed on a package substrate. An LED chip is arranged into a recession of the reflector. However, the mechanical arm of the mechanical installation equipment needs to work in the recession of the reflector, which reduces the yield of the LED.

Therefore, it is desirable to provide an LED package structure and a method for manufacturing the LED package structure which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the LED package structure and a method for manufacturing the LED package structure. Moreover, in the drawings, like reference numerals designate corresponding parts throughout the views.

FIG. 1 is a processing flow for manufacturing an LED package in accordance with a first embodiment.

FIG. 2 is a sectional view of two electrodes formed on a substrate.

FIG. 3 is a sectional view of an LED chip arranged on one of the electrodes of the substrate.

FIG. 4 is a top view of a shell provided by a third step in manufacturing the LED package.

FIG. 5 is a top view of a shell provided by the third step of manufacturing an LED package in accordance with a second embodiment.

FIG. 6 is a cross sectional view of an LED package in accordance with the first embodiment.

FIG. 7 is a top view of a shell to be assembled with the substrate and the LED chip in accordance with an alternative embodiment.

FIG. 8 is a top view showing the shell of FIG. 7 assembled with the substrate and the LED chip according to the alternative embodiment.

### DETAILED DESCRIPTION

Embodiments of an LED package structure and a method for manufacturing the LED package structure as disclosed are described in detail with reference to the drawings.

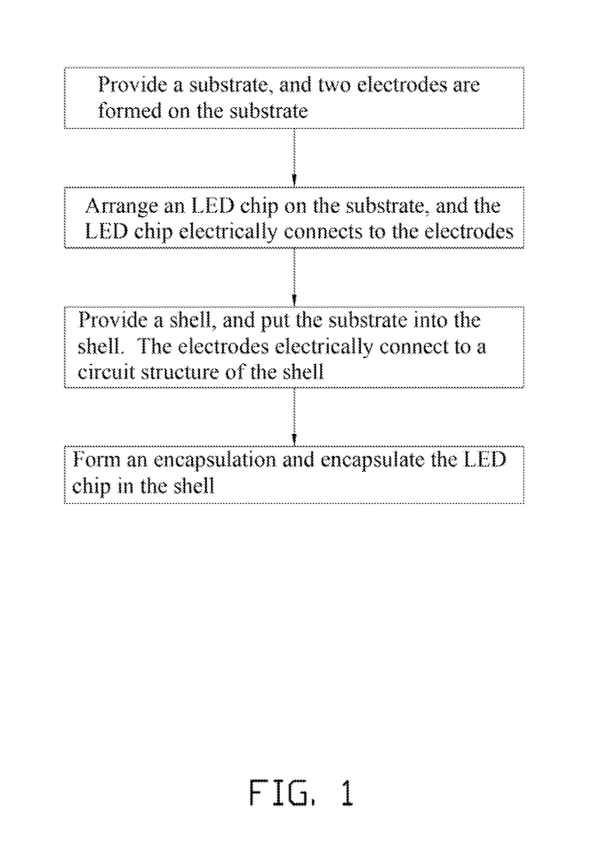

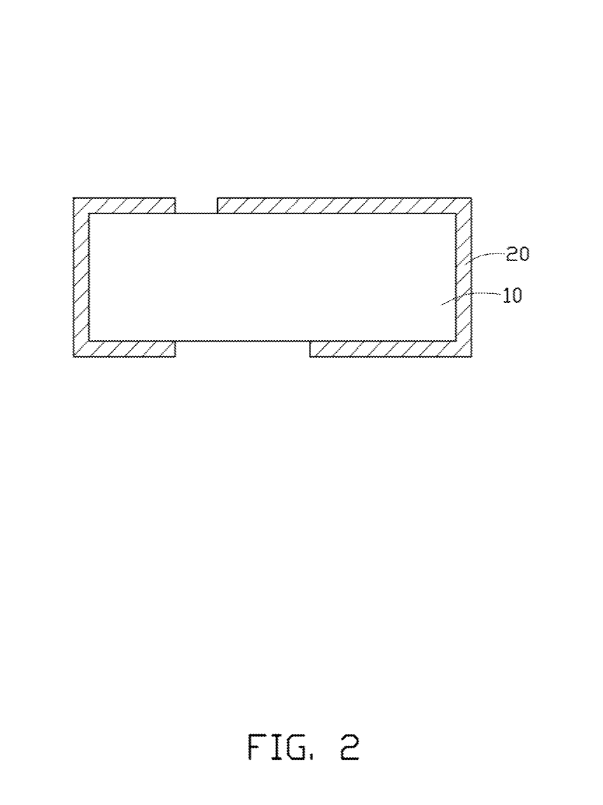

FIG. 1 shows a processing flow for manufacturing an LED package according to a first embodiment. Also referring to FIG. 2, in the process, a substrate 10 is provided, and the substrate 10 is a plate. Two electrodes 20 are formed on the substrate 10.

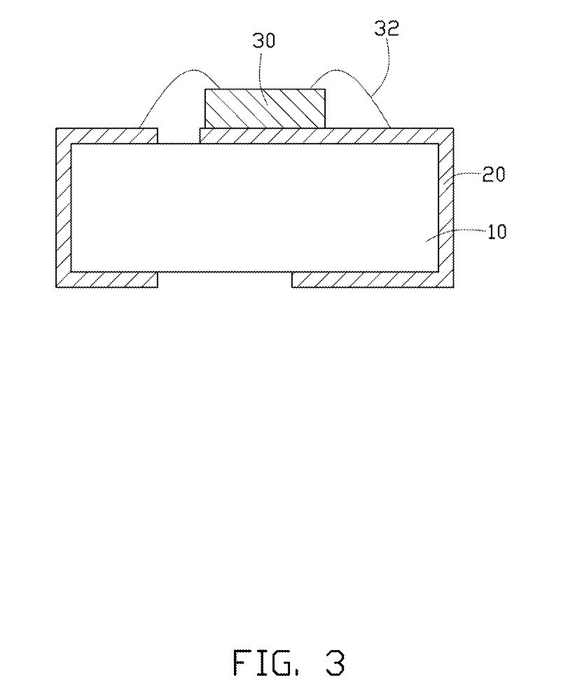

Referring to FIG. 3, an LED chip 30 is connected electrically to the electrodes 20 by wires 32. The substrate 10 being flat, the space for a wire bonder is not limited. Thus, the yield of manufacturing the LED increases.

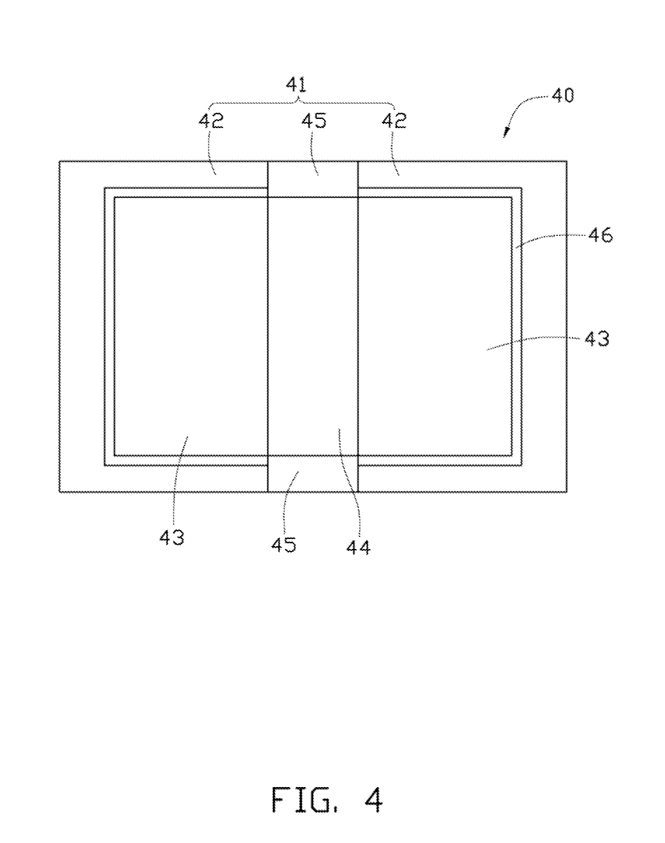

Referring to FIG. 4, a shell 40 is provided. The shell 40 includes a wall 41, a circuit structure 43 arranged on the bottom of the wall 41, and a metal layer 46 arranged on the inside wall of the wall 41.

The wall 41 is made up of two separate half-length walls 42. The two half-length walls 42 are metal in this embodiment. A rectangular frame is formed by an insulating layer represented by a connection block 45 and by the half-length walls 42. The length and width of the recession of the wall 41 is matched by the length and width of the substrate 10. Thus, the substrate 10 can be fittingly put inside the shell 40. The height of the wall 41 is larger than the thickness of the substrate 10, which ensures that the portion of the half-length walls 42 exposed above the substrate 10 forms a reflector structure.

The circuit structure 43 is made of conductive material as are the electrodes 20 electrically connecting thereto. The substrate 10 is arranged into the shell 40. The connection block 45 separates the circuit structure 43 into a right side and a left side, and the right side and the left side of the circuit structure 43 are electrically isolated from each other. A gap 44 is between the two halves of the circuit structure 43. The substrate 10 arranged into the shell 40 completes the electrical circuit, thus the electrodes 20 of the bottom of the substrate 20 make contact with the circuit structure 43 to form the necessary electrical connections.

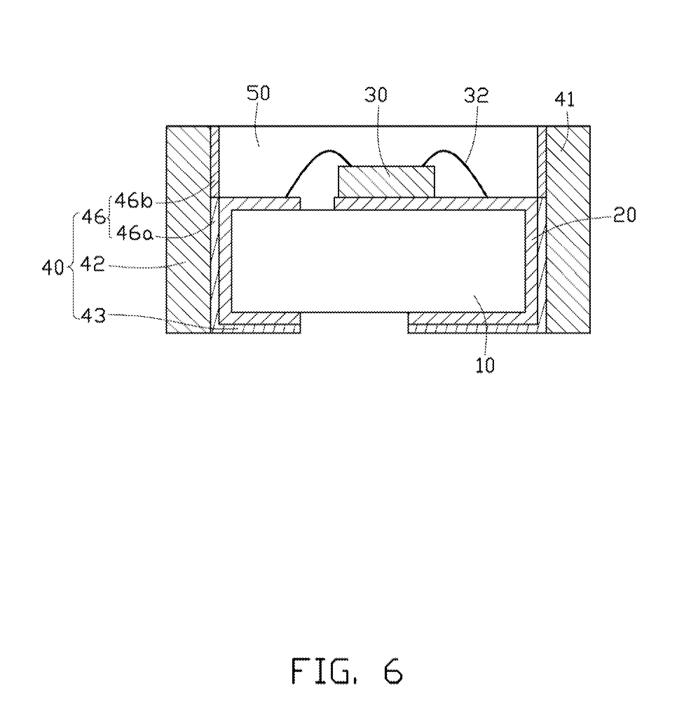

Referring to FIG. 6, the metal layer 46 includes a conductive layer 46a and a reflection layer 46b. The conductive layer 46a contacts the substrate 10. The conductive layer 46a is made of metal, such as copper. The reflection layer 46b above the substrate 10 is made of very reflective material, such as silver.

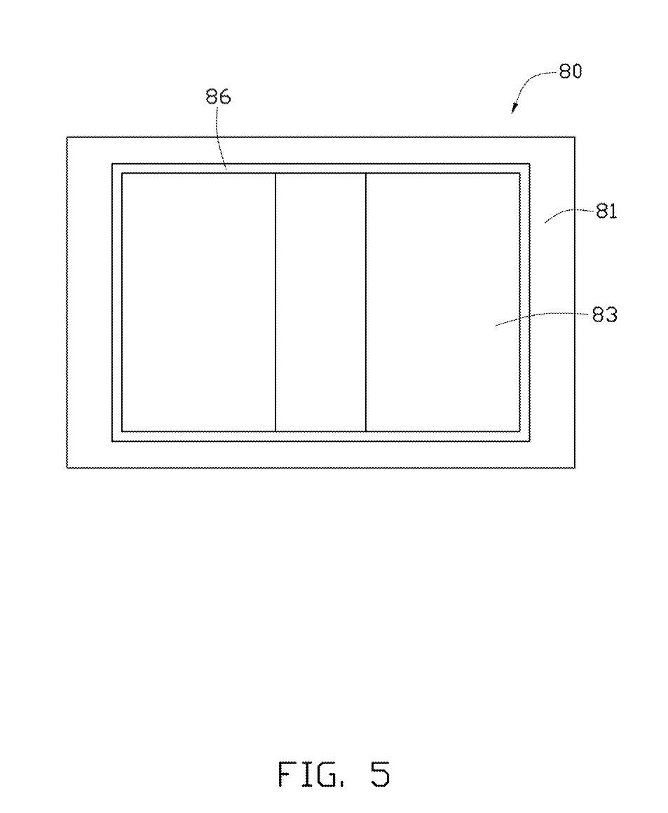

Referring to FIG. 5, a shell 80 includes a wall 81, a metal layer 86 attached on an inside wall of the wall 81, and a circuit structure 83 electrically insulated from the bottom of the wall 81, in a second embodiment. The wall 81 is rectangular, and formed in one piece, such as by injection molding. Then the metal layer 86 is formed in the inside wall. The height of the wall 81 exceeds the thickness of the substrate 10, and thus the wall 81 locates and fixes the substrate 10. However, the wall 81 is non-metallic.

Referring to FIG. 6, the LED chip 30 is within an encapsulation 50, formed in the shell 40. The encapsulation 50 is formed by a dispensing method. Encapsulating resin or glue is dispensed on the top surface of the substrate 10. The encapsulating glue covers the LED chip 30 and fills the area within the shell 40. A mold presses down on the top surface of the encapsulation 50 and the top surface of the shell 40. In another embodiment, the encapsulating glue can be mixed with phosphorus or other material with particular light-reflecting properties. Furthermore, a layer of phosphor (not shown) may be coated on the top surface of the encapsulation 50.

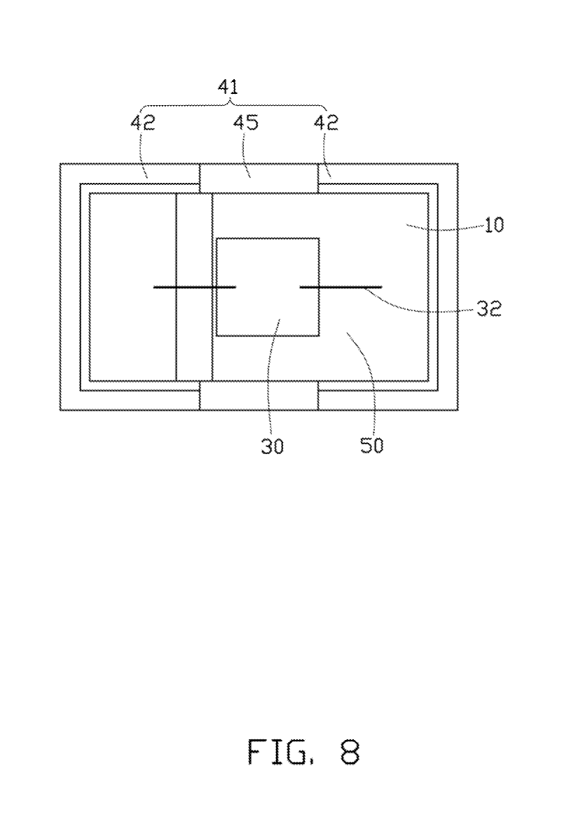

Referring to FIGS. 6 and 8, the LED package structure includes the substrate 10, the two electrodes 20 formed on the substrate 10, the LED chip 30 arranged on the substrate 10 and electrically connected to the electrodes 20, the shell 40 surrounding the substrate 10, and the encapsulation 50 which covers and seals the LED chip 30. The shell 40 includes the wall 41, and the height of the wall 40 exceeds the thickness of the substrate 10. The reflector is created by virtue of the wall 41 being higher than the substrate 10. The circuit structure 43 is arranged on the bottom of the wall 41 and the circuit structure 43 is accessible to electrodes 20 of the substrate 10.

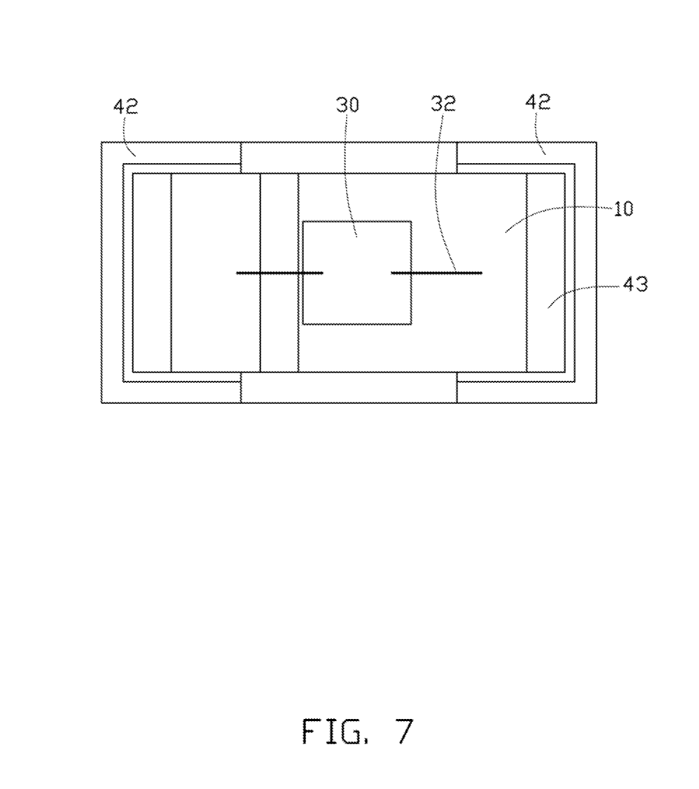

In addition to the shell 40 which is completed in advance and then the substrate and LED chip are put inside the shell 40 as disclosed in relation to FIG. 4, referring to FIG. 7, another assembling process is shown. In FIG. 7, the two symmetrical half-length walls 42 are provided. The half-length walls 42 are made of metal, and the circuit structure 43 is arranged at the bottom of the half-length walls 42. The two symmetrical half-length walls 42 are arranged at either end of the substrate 10. The total length of the two half-length walls 42 is less than the length of the substrate 10. A distance is between each of two opposite lateral sides of the substrate 10 and an inner side of an outer wall of each half-length wall 42.

Referring to FIG. 8, the half-length walls 42 are moved toward the substrate 10 until the inside walls of the two half-length walls 42 enclose a right side and a left side of the substrate 10. The two half-length walls 42 are still separated by a certain distance. And then, the connection block 45 may be formed by infilling with insulating glue. Thus, the two half-length walls 42 are accordingly fixed in place and electrically insulated from each other. The completed shell 40 is formed. And then, the encapsulation 50 is dispensed into the shell 40 so as to cover and protect the LED chip 30. The two half-length walls 42 can also be made of non-metallic materials.

While the disclosure has been described by way of example and in terms of exemplary embodiments, it is to be understood that the disclosure is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for manufacturing an LED package structure, including steps:
providing a substrate, forming two electrodes on the substrate;
arranging an LED chip on the substrate and electrically connecting to the electrodes;
providing a shell, the shell including a wall, a height of the wall exceeding a thickness of the substrate, a circuit structure being arranged on a bottom surface of the wall, the substrate being arranged inside the shell, the electrodes electrically connecting to the circuit structure; and
forming an encapsulation encapsulating the LED chip inside the shell.

2. The method for manufacturing the LED package structure of claim 1, wherein the wall includes two half-length walls separating mutually, and the two half-length walls are fixed by non-metallic materials.

3. The method for manufacturing the LED package structure of claim 1, wherein the wall is non-metallic materials and is formed in one piece.

4. The method for manufacturing the LED package structure of claim 1, wherein an inside wall of the wall is metal layer, the metal layer includes a conductive layer and a reflection layer, the conductive layer contacts the substrate, and the reflection layer is above and beside the substrate.

5. The method for manufacturing the LED package structure of claim 2, wherein the step of the substrate being arranged inside the shell is that the two half-length walls are fixed by non-metal material and form the shell, and then push the substrate into the shell.

6. The method for manufacturing the LED package structure of claim 2, wherein the step of the substrate being arranged inside the shell is that the two half-length walls are moved toward the substrate until inside walls of the two half-length walls close two sides of the substrate, and then, the connection block is formed by filling non-metal materials in a gap between the two half-length walls, and the two half-length walls are fixed.

7. The method for manufacturing the LED package structure of claim 1, wherein the step of the substrate being arranged inside the shell is that push the substrate into the shell in a perpendicular direction, and the electrodes contact the circuit structure.

8. An LED package structure, comprising: a substrate, two electrodes arranged on the substrate, an LED chip arranged on the substrate and electrically connecting to the electrodes, and an encapsulation covering the LED chip, wherein further includes a shell surrounding the substrate and the encapsulation, the shell includes a wall, a height of the wall exceeds a thickness of the substrate, a circuit structure is arranged on a bottom of the wall, and the circuit structure electrically connects to the electrodes.

9. The LED package structure of claim 8, wherein the wall includes two half-length walls separating mutually, and the two half-length walls are fixed by non-metal material.

10. The LED package structure of claim 8, wherein the wall is non-metallic materials and is formed in one piece.
